(19) United States
(12) Patent Application Publication
(10) Pub. No.: US 2025/0072032 A1
(43) Pub. Date: Feb. 27, 2025

(54) SEMICONDUCTOR POWER DEVICE

(71) Applicant: Industrial Technology Research Institute, Hsinchu (TW)

(72) Inventors: Shin-Yi Huang, Hsinchu County (TW); Hua-Mao Chen, Tainan City (TW); Chih-Hung Yen, Hsinchu County (TW)

(73) Assignee: Industrial Technology Research Institute, Hsinchu (TW)

(21) Appl. No.: 18/484,430

(22) Filed: Oct. 10, 2023

(30) Foreign Application Priority Data
Aug. 23, 2023 (TW) 112131602

(51) Int. Cl. H01L 29/778; H01L 29/08; H01L 29/20; H01L 29/417

(52) U.S. Cl. CPC H01L 29/7786; H01L 29/0843; H01L 29/2003; H01L 29/41775

(57) ABSTRACT

A semiconductor power device includes a substrate, a channel layer, a barrier layer, a gate, a source, and a drain. The channel layer is located on the substrate. The barrier layer is located on the channel layer and includes a first region and a second region outside the first region. There is a first compound in the first region and a second compound in the second region. The first compound and the second compound each have an aluminum atom of a different ratio, and the aluminum composition ratio of the first compound is less than the aluminum composition ratio of the second compound. The ratio consists of a plurality of different atoms in the first compound and the second compound.

### CROSS-REFERENCE TO RELATED APPLICATION

This application claims the priority benefit of Taiwan application serial no. 112131602, filed on Aug. 23, 2023. The entirety of the above-mentioned patent application is hereby incorporated by reference herein and made a part of this specification.

### TECHNICAL FIELD

The disclosure relates to a semiconductor power component.

### BACKGROUND

In recent years, in response to the demand for high-frequency semiconductor devices, semiconductor power devices have developed into III-V semiconductor power devices, such as AlGaN—GaN HEMT devices. The AlGaN—GaN HEMT device is a high electron mobility transistor with AlGaN as the Schottky barrier. Due to spontaneous polarization and piezoelectric polarization effects, a two-dimensional electron gas (2DEG) layer is formed at the interface between the AlGaN layer and the GaN channel layer. Through factors such as the high electron mobility of the electron itself, the high concentration of electrons in the 2DEG, and the low sheet resistance of gallium nitride, III-V semiconductor materials are suitable for high-frequency applications.

As semiconductor devices develop towards higher frequency and higher voltage systems, the breakdown voltage and critical electric field that the above-mentioned III-V semiconductor materials can withstand have reached the limits. The current research and development trend of semiconductor power devices is towards higher frequency and higher voltage semiconductor devices, such as semiconductor power devices consisting of gallium oxide (Ga₂O₃) material with high energy gap (Eg=4.9 eV).

However, since the Ga₂O₃ material itself has a problem of low electron mobility, the on-resistance of the semiconductor power device can increase. In addition, since the Ga₂O₃ material is an oxide, semiconductor power devices are also prone to heat accumulation problems.

### SUMMARY

The semiconductor power device provided by the disclosure can increase the concentration of two-dimensional electron gas (2DEG) in a non-gate region and reduce the on-resistance.

A semiconductor power device of the disclosure includes a substrate, a channel layer, a barrier layer, a gate, a source, and a drain. The channel layer is located on the substrate. The barrier layer is located on the channel layer. The barrier layer includes a first region and a second region outside the first region. There is a first compound in the first region and a second compound in the second region. The first compound and the second compound each have an aluminum atom of a different ratio. The ratio consists of a plurality of different atoms in the first compound and the second compound. The source and the drain are respectively located on the second region. The gate is located between the source and the drain and on the first region. The gate, the source, and the drain each comprise Au, Al, Ti, Sn, Ge, In, Ni, Co, Pt, W, Mo, Cr, Cu, Pb, Ti/Al, Ti/Au, Ti/Pt, Al/Au, Ni/Au, or Au/Ni.

Another semiconductor power device of the disclosure includes a substrate, a channel layer, a barrier layer, a gate, an insulating layer, a source, and a drain. The channel layer is located on the substrate. The barrier layer is located on the channel layer and has an opening. The barrier layer is an aluminum compound. The aluminum compound includes an aluminum atom consisting of one ratio and a gallium atom consisting of another ratio, which represents that the gallium atom replaces a part of the aluminum atom. A gate is located on the barrier layer and filled in the opening. The insulating layer is located between the gate and the channel layer and is in direct contact with the channel layer. The source and drain are respectively located on the barrier layer on two sides of the gate.

Another semiconductor power device of the disclosure has at least one original physical property before being doped with an aluminum ion, and the aluminum ion improves the original physical property after the semiconductor power device is doped with the aluminum ion. The semiconductor power device doped with the aluminum ion includes a substrate, a channel layer, a barrier layer, a gate, an insulating layer, a source, and a drain. The substrate is represented by a first chemical formula. The first chemical formula includes an element semiconductor or a compound semiconductor. The channel layer is located on the substrate and is represented by a second chemical formula. The second chemical formula includes another compound semiconductor. The barrier layer is located on the channel layer. The barrier layer includes at least one compound. The compound located in at least one region of the barrier layer is represented by a third chemical formula. The compound consists of a ratio of aluminum atom. The source and the drain are compositions having a metal material. The source and the drain are each independently located on the region. The gate is a metal composition. The gate is located between the source and the drain and outside the region.

Based on the above, the semiconductor power device of the disclosure can reduce the resistance of the non-gate region through a barrier layer of the non-gate region with a high Al composition ratio. Whether it is a GaN-based semiconductor power device or a semiconductor power device using Ga₂O₃, the on-resistance of the device can be reduced and the problem of heat accumulation can be solved. At the same time, the disclosure can appropriately reduce the Al composition ratio around the channel in the semiconductor power device to avoid an increase in stress, thereby improving the reliability of the gate. In addition, the barrier layer with a relatively low Al composition ratio under the gate can make the critical voltage value (Vt) of the device closer to a “positive value”, that is, close to the operation of an enhancement mode (E-mode) transistor, which is convenient for device applications.

### BRIEF DESCRIPTION OF THE DRAWINGS

The accompanying drawings are included to provide a further understanding, and are incorporated in and constitute a part of this specification. The drawings illustrate example embodiments and, together with the description, serve to explain the principles of the disclosure.

FIG. 1 is a schematic cross-sectional diagram of a semiconductor power device according to a first embodiment of the disclosure.

FIG. 2 shows a carrier concentration as a function of an aluminum composition ratio of a barrier layer.

FIG. 3 shows a sheet resistance changing according to an aluminum composition ratio of the barrier layer 104.

FIG. 4 is an I-V curve diagram (linear plot) of a semiconductor power device of a simulation experiment example.

FIG. 5 is an I-V curve diagram (logarithmic plot) of a semiconductor power device of a simulation experiment example.

FIG. 6 is a schematic cross-sectional diagram of a semiconductor power device according to a second embodiment of the disclosure.

FIG. 7 is a schematic cross-sectional diagram of a semiconductor power device according to a third embodiment of the disclosure.

FIG. 8 is a schematic cross-sectional diagram of a semiconductor power device according to a fourth embodiment of the disclosure.

### DETAILED DESCRIPTION OF DISCLOSURED EMBODIMENTS

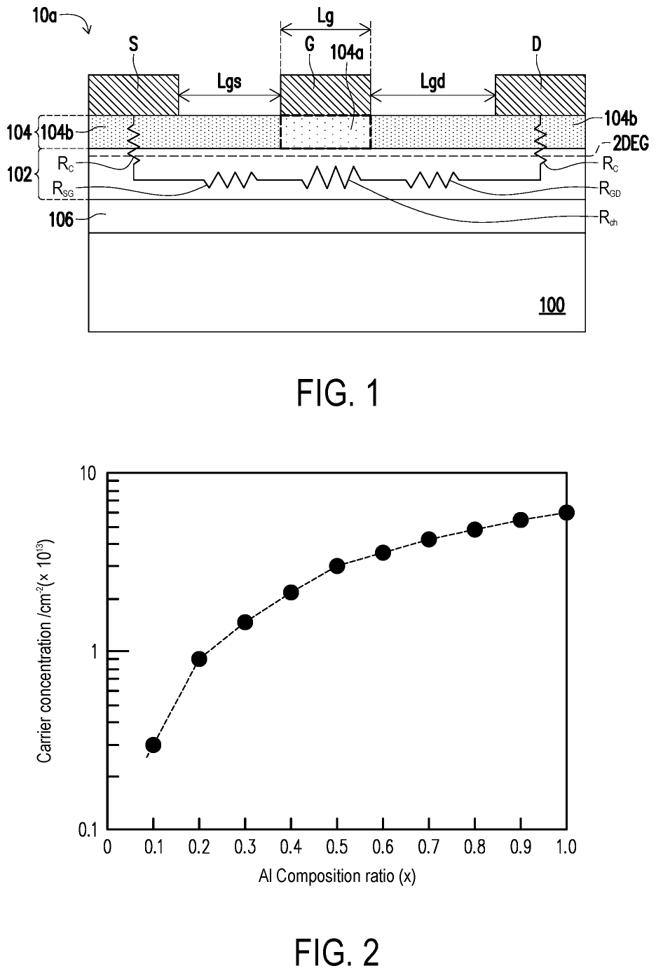

FIG. 1 is a schematic cross-sectional diagram of a semiconductor power device according to a first embodiment of the disclosure.

Referring to FIG. 1, a semiconductor power device 10a of the first embodiment basically includes a substrate 100, a channel layer 102, a barrier layer 104, a gate G, a source S, and a drain D. The substrate 100 is represented by a first chemical formula, which includes an element semiconductor or a compound semiconductor, such as, but not limited to, silicon carbide (SiC), silicon (Si), gallium nitride (GaN), sapphire, gallium oxide (Ga₂O₃), or polycrystalline aluminum nitride (poly-AlN). The channel layer 102 is located on the substrate 100. The channel layer 102 is represented by a second chemical formula. The second chemical formula includes another compound semiconductor. In an embodiment, the channel layer 102 can be GaN, indium gallium nitride (InGaN), or gallium oxide (Ga₂O₃, also referred to as β-Ga₂O₃). A barrier layer 104 is located on the channel layer 102. A two-dimensional electron gas 2DEG generated in the first embodiment always exists at the interface of the channel layer 102 close to the barrier layer 104, so the semiconductor power device 10a belongs to a depletion mode (D-mode) transistor, which is turned on in a normal state. In addition, a buffer layer 106 or other functional film layers can be provided between the substrate 100 and the channel layer 102. For example, the buffer layer 106 can be AlN or aluminum gallium nitride (AlGaN)/GaN superlattice structure, or the like.

The barrier layer 104 includes at least one compound. The compound located in at least one region of the barrier layer 104 is represented by a third chemical formula. The compound includes an aluminum atom consisting of a ratio. For example, the barrier layer 104 in the first embodiment includes a first region 104a and a second region 104b outside the first region 104a. There is a first compound in the first region 104a and a second compound in the second region 104b. The first compound and the second compound each have an aluminum atom of a different ratio. The ratio consists of a plurality of different atoms in the first compound and the second compound. In other words, the first compound includes one aluminum atom consisting of a first ratio, the second compound includes another aluminum atom consisting of a second ratio, and the first ratio and the second ratio are different. In the first embodiment, the first ratio is less than the second ratio; that is, the aluminum composition ratio of the first compound is less than the aluminum composition ratio of the second compound.

In an embodiment, the first compound further includes one gallium atom, which replaces a part of the aluminum atom in the first compound. The second compound further includes another gallium atom, which replaces a part of the said aluminum atom in the second compound. For example, the first compound in the first region 104a of the barrier layer 104 is AlₓGa₍₁₋ₓ₎N, and the second compound in the second region 104b of the barrier layer 104 is Al_{y}Ga_{(1-y)}N, where x represents the first ratio and y represents the second ratio, and y>x>0. The first compound in the first region 104a of the barrier layer 104 is InₓGa₍₁₋ₓ₎N, and the second compound in the second region 104b of the barrier layer 104 is Al_{y}InₓGa_{(1-x-y)}N, where x represents the first ratio and y represents the second ratio, and y>0, (x+y)<1. The first compound in the first region 104a of the barrier layer 104 is (AlₓGa₁₋ₓ)₂O₃, and the second compound in the second region 104b of the barrier layer 104 is (Al_{y}Ga_{1-y})₂O₃, where x represents the first ratio and y represents the second ratio, and y>x>0; and so on.

The manufacturing method of the barrier layer 104 can be, for example, but not limited to: after epitaxially growing the buffer layer 106, the channel layer 102, and the barrier layer on the substrate 100 (for example, fully forming the first compound), firstly forming the gate G on the surface of the barrier layer, and then performing an aluminum (Al⁺) ion implantation process to dope the second region 104b outside the first region 104a with aluminum, so that at least one of the original physical properties (such as carrier concentration, etc.) that the semiconductor power device 10a has before being doped with an aluminum ion is improved due to being doped with the aluminum ion. After the aluminum ion implantation process, the first compound in the second region 104b becomes a second compound with a larger aluminum composition ratio. The aluminum composition ratio of the second compound in the second region 104b can be converted through material analysis (such as EDS analysis).

Continuing to refer to FIG. 1, each of the source S and the drain D is located on the second region 104b. The gate G is located between the source S and the drain D and on the first region 104a. The source S and the drain D are compositions having a metal material. The gate G is a metal composition. In an embodiment, the gate G, the source S, and the drain D each include gold (Au), aluminum (Al), titanium (Ti), tin (Sn), germanium (Ge), indium (In), nickel (Ni), cobalt (Co), platinum (Pt), tungsten (W), molybdenum (Mo), chromium (Cr), copper (Cu), lead (Pb), Ti/Al, Ti/Au, Ti/Pt, Al/Au, Ni/Au, or Au/Ni. The material of the gate G can be the same as or different from the source S and drain D. In FIG. 1, although a distance Lgs from the gate G to the source S is similar to a distance Lgd from the gate G to the drain D, from the perspective of increasing the breakdown voltage, the distance Lgd from the gate to the drain is much greater than the distance Lgs from the gate to the source.

The carrier concentration relationship of the first region 104a below the gate G (low Al composition ratio region) and the second region 104b outside the gate G (high Al composition ratio region) is as shown in FIG. 2. It can be seen from FIG. 2 that the higher the Al composition ratio (x), the greater the carrier concentration.

That is to say, in FIG. 1, the concentration of the two-dimensional electron gas 2DEG generated below the second region 104b outside the first region 104a is greater than the concentration of the two-dimensional electron gas 2DEG generated below the first region 104a. Since an on-resistance Ron of the semiconductor power device 10a consists of 2R_{c}+R_{ch}+R_{SG}+R_{GD} (R_{c} refers to the contact resistance, R_{ch} refers to the channel resistance below the gate G, R_{SG} refers to the source-gate resistance, R_{GD} refers to the gate-drain resistance), once the carrier concentration generated below the second region 104b increases, the source-gate resistance R_{SG} and the gate-drain resistance R_{GD} can decrease, thereby reducing the on-resistance Ron. The first region 104a which maintains a relatively low Al composition ratio can prevent the barrier layer 104 from increasing stress, thereby improving the reliability of the gate G without having too much impact on the on-resistance Ron.

Moreover, when the channel layer 102 is a gallium oxide (β-Ga₂O₃) material, since β-Ga₂O₃ has a high energy gap (Eg=4.9 eV) and a high dielectric collapse electric field (Ec=6.5 MV/cm) but an electron mobility of only about 200 cm²/V·s, doping aluminum to increase the aluminum composition ratio of the second compound in the second region 104b can increase the electron mobility of β-Ga₂O₃ and reduce the on-resistance Ron, which is critical to the development of gallium oxide power devices.

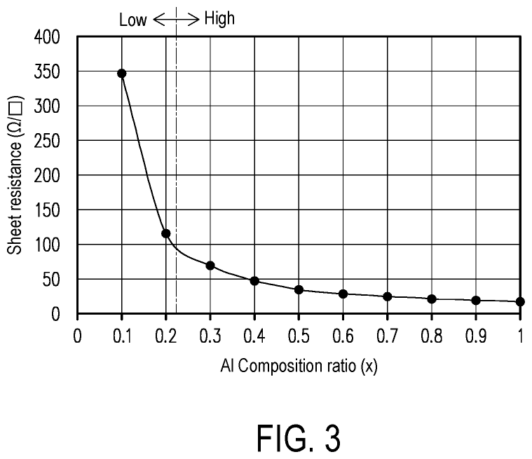

FIG. 3 shows a sheet resistance changing according to an aluminum composition of the barrier layer 104. As shown in FIG. 3, when the Al composition ratio (x) is less than 0.23, the sheet resistance is >100 Ω/sq; when the Al composition ratio (x) is greater than 0.23, the sheet resistance is <100 Ω/sq. Therefore, the Al composition ratio (x) can be set as 0.23 as the boundary, which defines that the Al composition ratio (x) of the first region 104a is less than 0.23 (i.e., low aluminum concentration), and the Al composition ratio (x) of the second region 104b is greater than or equal to 0.23 (i.e., high aluminum concentration). However, the disclosure is not limited thereto. Depending on the device design and requirements of the semiconductor power device 10a, the boundary of the Al composition ratio (x) can also be greater than 0.23 or less than 0.23.

Continuing to refer to FIG. 1, the aluminum concentration in the second region 104b is greater than the aluminum concentration in the first region 104a, which has the effect of reducing the on-resistance Ron. As for the upper limit of the aluminum concentration in the second region 104b, there is no limit. If low leakage is taken into consideration, the upper limit of the Al composition ratio (x) of the second region 104b is 0.8. For example, the aluminum composition ratio (x) in the material of the second region 104b can be 0<x<0.8 or 0.2<x<0.8 or 0.25<x<0.7. In addition, if the material of the barrier layer 104 contains indium, the indium composition ratio of the first region 104a can be greater than the indium composition ratio of the second region 104b, since if the indium composition ratio is low, the polarization effect can become stronger and the resistance can decrease. The indium composition ratio of the first region 104a is, for example, less than 0.8.

The following experiment examples are illustrated by simulation to describe the effect of the disclosure, but the disclosure is not limited to the following contents.

### Simulation Experiment Example

The simulated semiconductor power device was shown in FIG. 1. The channel layer was GaN, a gate length Lg was set to 1.4 μm, the distance Lgs from the gate to the source was set to 1 μm, the distance Lgd from the gate to the drain was set to 6 μm, the first compound in the first region was Al_{0.05}Ga_{0.95}N (the Al composition ratio (x) was fixed at 0.05), and the second compound in the second region was AlₓGa₁₋ₓN (the Al composition ratio was a variable (x=0.23, x=0.4, x=0.6, x=0.8)).

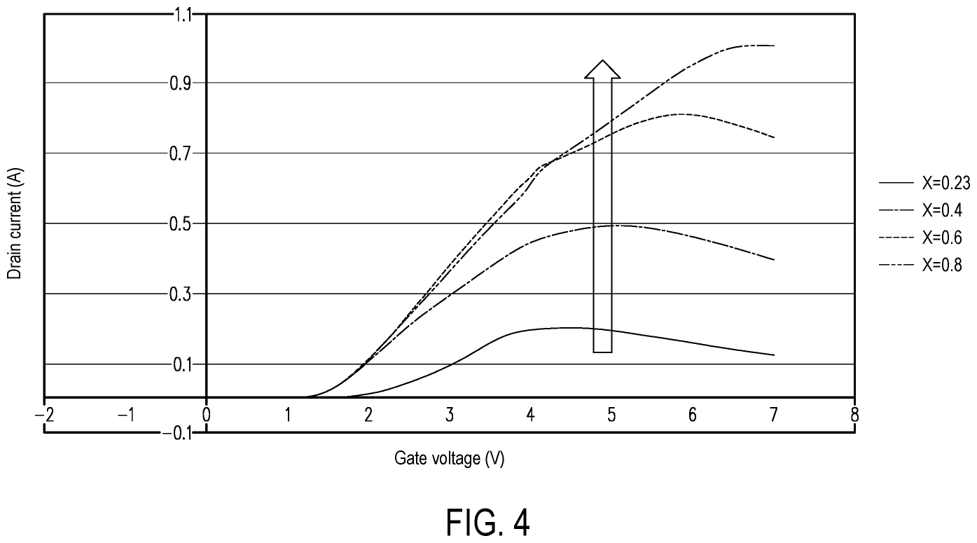

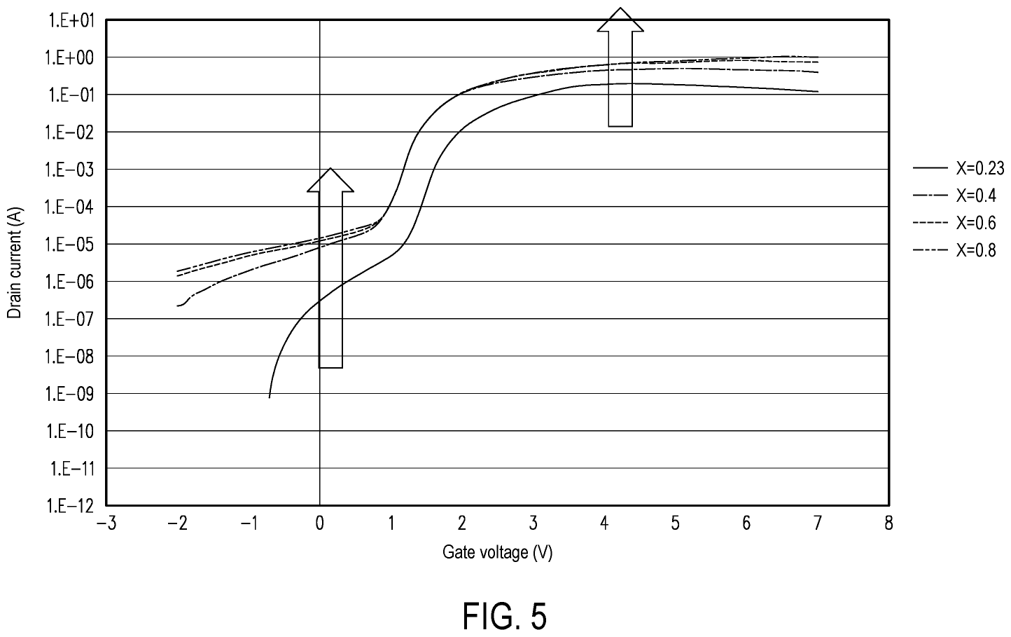

FIG. 4 is an I-V curve diagram (linear plot) of a semiconductor power device of a simulation experiment example. FIG. 5 is an I-V curve diagram (logarithmic plot) of a semiconductor power device of a simulation experiment example. It can be seen from FIG. 4 and FIG. 5 that the higher the Al composition ratio (x), the greater the drain current. Therefore, the increase in the Al composition ratio (x) did have the effect of reducing the device resistance.

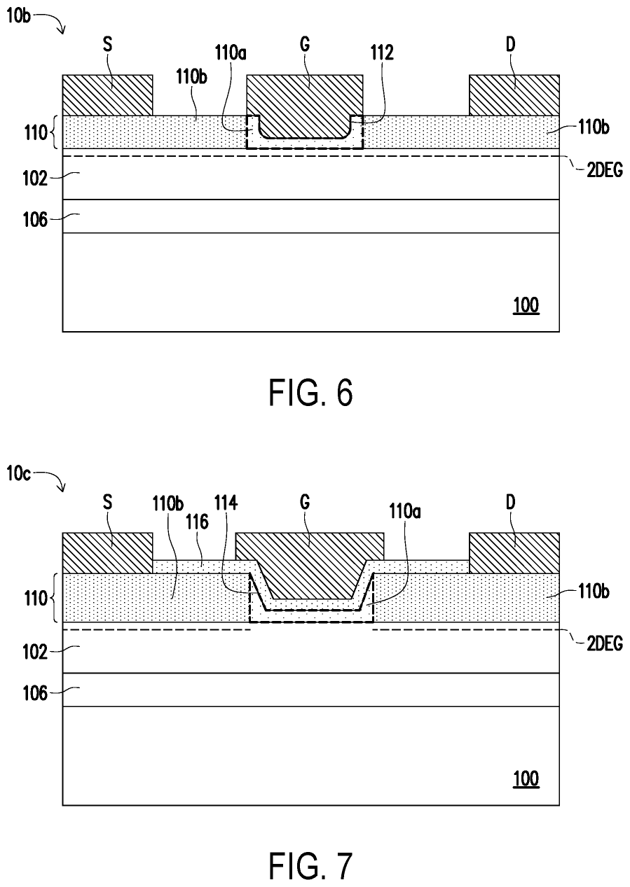

FIG. 6 is a schematic cross-sectional diagram of a semiconductor power device according to a second embodiment of the disclosure. The same reference numerals as the reference numerals used in the first embodiment are used to represent the same or similar parts and components, and reference can be made to the related content of the first embodiment for the same or similar parts and components and are not be repeated.

Referring to FIG. 6, the difference between a semiconductor power device 10b of the second embodiment and the first embodiment is that a barrier layer 110 has a notch 112 in a first region 110a, and the gate G is filled in the notch 112. The barrier layer 110 in the second embodiment also includes a first region 110a and a second region 110b outside the first region 110a. The source S and the drain D are respectively located on the second region 110b, and the gate G is located between the source S and the drain D and on the first region 110a. There is a first compound in the first region 110a and a second compound in the second region 110b. For the first compound and the second compound, reference can be made to the description of the first embodiment and the details are not be repeated. Due to the design of the notch 112, the distance between the gate G and the channel layer 102 is shorter, thereby reducing the channel resistance here, so that the two-dimensional electron gas 2DEG below the first region 110a is increased, and the on-resistance Ron is reduced. The semiconductor power device 10b of the second embodiment also belongs to the D-mode transistor.

FIG. 7 is a schematic cross-sectional diagram of a semiconductor power device according to a third embodiment of the disclosure. The same reference numerals as the reference numerals used in the second embodiment are used to represent the same or similar parts and components, and reference can be made to the related content of the second embodiment for the same or similar parts and components and are not be repeated.

Referring to FIG. 7, the difference between a semiconductor power device 10c of the third embodiment and the second embodiment is that a notch 114 is slightly larger than the notch (112) of the second embodiment, and there is a dielectric layer 116 between the barrier layer 110 and the gate G. The dielectric layer 116 can be a general dielectric layer, such as SiO₂, SiON, or SiN; the dielectric layer 116 can also be a high dielectric coefficient (high-k) material, such as Al₂O₃, HfO₂, ZrO₂, or other suitable high-k materials. Due to the existence of the dielectric layer 116, the two-dimensional electron gas 2DEG is not generated below the first region 110a, so the semiconductor power device 10c belongs to an enhancement mode (E-mode) transistor, which is turned off in a normal state.

In the third embodiment, the manufacturing method of the semiconductor power device 10c includes, but is not limited to, after epitaxially growing the buffer layer 106, the channel layer 102, and the barrier layer on the substrate 100 (for example, fully forming the first compound), firstly forming a first patterned mask (not shown) on the surface of the barrier layer to cover the first region 110a, and then performing an aluminum (Al⁺) ion implantation process to dope the second region 110b outside the first region 110a with aluminum, so that the first compound in the second region 110b becomes a second compound with a larger aluminum composition ratio. Next, after removing the first patterned mask, a second patterned mask (not shown) is used to cover the second region 110b, and then etching is performed to form a notch 114. Then, after removing the second patterned mask, the dielectric layer 116 is formed on the surface of the barrier layer 110 (including the first region 110a and the second region 110b), and then the gate G is formed to fill the notch 114. Finally, the source S and the drain D are formed through the dielectric layer 116 to be in contact with the second region 110b.

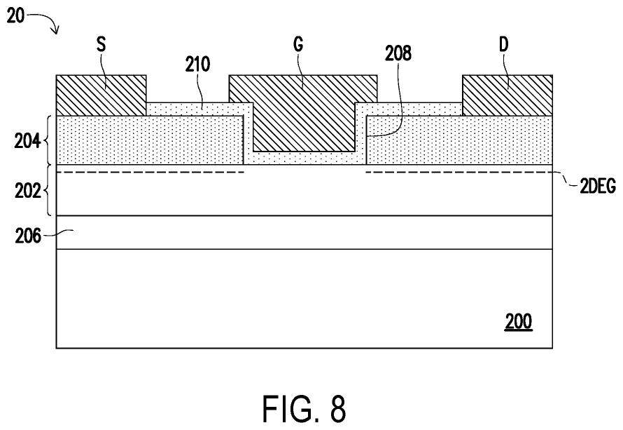

FIG. 8 is a schematic cross-sectional diagram of a semiconductor power device according to a fourth embodiment of the disclosure.

Referring to FIG. 8, a semiconductor power device 20 of the fourth embodiment basically includes a substrate 200, a channel layer 202, a barrier layer 204, a gate G, an insulating layer 210, a source S, and a drain D. The substrate 200 can include, but is not limited to, SiC, Si, GaN, sapphire, Ga₂O₃, or polycrystalline aluminum nitride (poly-AlN). The channel layer 202 is located on substrate 200. In an embodiment, the channel layer 202 is, for example, GaN, InGaN, or Ga₂O₃ (or referred to as β-Ga₂O₃). The barrier layer 204 is located on the channel layer 202 and has an opening 208. The barrier layer 204 is an aluminum compound. The aluminum compound includes an aluminum atom consisting of a first ratio and a gallium atom consisting of a second ratio. The second ratio represents that the gallium atom replaces a part of the aluminum atom, such as AlₐGa₍₁₋ₐ₎N, AlₐIn_{b}Ga_{(1-a-b})N, or (AlₐGa₁₋ₐ)₂O₃, where a<1 and (a+b)<1, and a represents the ratio of aluminum, b represents the ratio of indium, and each of 1−a and 1−a−b represents different ratios of gallium. In addition, there is a buffer layer 206 or other functional film layers provided between the substrate 200 and the channel layer 202. For example, the buffer layer 206 can be AlN or AlGaN/GaN superlattice structure, or the like. The gate G is located on the barrier layer 204 and is filled in the opening 208. The insulating layer 210 is located between the gate G and the channel layer 202 and is in direct contact with the channel layer 202. The insulating layer 210 includes SiO₂, SiON, SiN, or high dielectric coefficient (high-k) materials, such as Al₂O₃, HfO₂, ZrO₂, or other suitable high-k materials.

Continuing to refer to FIG. 8, each of the source S and the drain D is located on the barrier layer 204 on two sides of the gate G. The gate G, source S, and drain D each include Au, Al, Ti, Sn, Ge, In, Ni, Co, Pt, W, Mo, Cr, Cu, Pb, Ti/Al, Ti/Au, Ti/Pt, Al/Au, Ni/Au, or Au/Ni. In an embodiment, the material of the gate G is the same as the source S and the drain D; in another embodiment, the material of the gate G is different from the source S and the drain D. In addition, if the distance from the gate G to the drain D is greater than the distance from the gate G to the source S, the performance of the semiconductor power device 20 can be improved.

In summary, the disclosure increases the aluminum composition ratio of the compound in the region outside the gate through ion implantation, thereby increasing the electron concentration of the two-dimensional electron gas (2DEG) of the region and reducing the on-resistance (Ron) of the overall device. Whether it is a GaN-based semiconductor power device or a semiconductor power device using Ga₂O₃, doping with an aluminum ion can effectively reduce the on-resistance of the device, and especially improving the electron mobility of β-Ga₂O₃ and solving the problem of heat accumulation. In other words, doping the aluminum ion to form a ratio of aluminum compounds in semiconductor power devices is critical to the development of gallium oxide power devices. In addition, the disclosure can appropriately reduce the aluminum composition ratio of the compound in the region below the gate to avoid an increase in barrier layer stress, thereby improving the reliability of the gate. In addition, the semiconductor power device of the disclosure can be a depletion mode (D-mode) transistor or an enhancement mode (E-mode) transistor, and so has wider applicability.

It will be apparent to those skilled in the art that various modifications and variations can be made to the structure of the disclosed embodiments without departing from the scope or spirit of the disclosure. In diagram of the forwarding, it is intended that the disclosure cover modifications and variations of this disclosure provided they fall within the scope of the following claims and their equivalents.

What is claimed is:

1. A semiconductor power device, comprising:
a substrate;
a channel layer, located on the substrate;
a barrier layer, located on the channel layer, wherein the barrier layer comprises a first region and a second region outside the first region, there is a first compound in the first region and a second compound in the second region, the first compound and the second compound each have an aluminum atom of a different ratio, the ratio consists of a plurality of different atoms in the first compound and the second compound, and an aluminum composition ratio of the first compound is less than an aluminum composition ratio of the second compound;
a source and a drain, wherein the source and the drain are respectively located on the second region; and
a gate, located between the source and the drain and on the first region, wherein the gate, the source, and the drain each comprise Au, Al, Ti, Sn, Ge, In, Ni, Co, Pt, W, Mo, Cr, Cu, Pb, Ti/Al, Ti/Au, Ti/Pt, Al/Au, Ni/Au, or Au/Ni.

2. The semiconductor power device according to claim 1, wherein the first compound further comprises a gallium atom, which replaces a part of the aluminum atom in the first compound, and the second compound further comprises another gallium atom, which replaces a part of the aluminum atom in the second compound.

3. The semiconductor power device according to claim 1, wherein the aluminum composition ratio of the second compound is less than 0.8.

4. The semiconductor power device according to claim 1, wherein the channel layer comprises GaN, InGaN, or Ga₂O₃.

5. The semiconductor power device according to claim 1, wherein the first compound comprises AlₓGa₍₁₋ₓ₎N, and the second compound comprises Al_{y}Ga_{(1-y)}N, wherein x represents a first ratio and y represents a second ratio, and y>x>0.

6. The semiconductor power device according to claim 1, wherein the first compound comprises InₓGa₍₁₋ₓ₎N, and the second compound comprises Al_{y}InₓGa_{(1-x-y)}N, wherein x represents a first ratio and y represents a second ratio, and y>0 and (x+y)<1.

7. The semiconductor power device according to claim 1, wherein the first compound comprises (AlₓGa₁₋ₓ)₂O₃, and the second compound comprises (Al_{y}Ga_{1-y})₂O₃, wherein x represents a first ratio and y represents a second ratio, and y>x>0.

8. The semiconductor power device of claim 1, wherein the barrier layer comprises indium, and an indium composition ratio of the first region is greater than an indium composition ratio of the second region.

9. The semiconductor power device according to claim 1, wherein the barrier layer has a notch in the first region, and the gate is filled in the notch.

10. The semiconductor power device according to claim 9, further comprising a dielectric layer located between the barrier layer and the gate.

11. The semiconductor power device according to claim 1, further comprising a buffer layer located between the substrate and the channel layer.

12. The semiconductor power device according to claim 1, wherein the substrate comprises SiC, Si, GaN, sapphire, Ga₂O₃, or polycrystalline aluminum nitride (poly-AlN).

13. A semiconductor power device, comprising:
a substrate;
a channel layer, located on the substrate;
a barrier layer, located on the channel layer, and having an opening, wherein the barrier layer is an aluminum compound, the aluminum compound comprises an aluminum atom consisting of a ratio and a gallium atom consisting of another ratio, which represents that the gallium atom replaces a part of the aluminum atom;
a gate, located on the barrier layer, and being filled in the opening; and
an insulating layer, located between the gate and the channel layer, and being in direct contact with the channel layer; and
a source and a drain, wherein the source and the drain are respectively located on the barrier layer on two sides of the gate.

14. The semiconductor power device according to claim 13, wherein the insulating layer is a high dielectric coefficient (high-k) material.

15. The semiconductor power device according to claim 13, wherein the channel layer is GaN, InGaN, or Ga₂O₃, and the aluminum compound is AlₐGa₍₁₋ₐ₎N, AlₐIn_{b}Ga_{(1-a-b)}N, or (AlₐGa₁₋ₐ)₂O₃, wherein a<1 and (a+b)<1, a represents a ratio of aluminum, b represents a ratio of indium, and 1−a and 1−a−b each represent different ratios of gallium.

16. The semiconductor power device according to claim 13, further comprising a buffer layer located between the substrate and the channel layer.

17. The semiconductor power device according to claim 13, wherein the gate, the source, and the drain each comprise Au, Al, Ti, Sn, Ge, In, Ni, Co, Pt, W, Mo, Cr, Cu, Pb, Ti/Al, Ti/Au, Ti/Pt, Al/Au, Ni/Au, or Au/Ni.

18. The semiconductor power device according to claim 13, wherein the substrate comprises SiC, Si, GaN, sapphire, Ga₂O₃, or polycrystalline aluminum nitride (poly-AlN).

19. A semiconductor power device, wherein the semiconductor power device has at least one original physical property before being doped with an aluminum ion, the aluminum ion improves the original physical property after the semiconductor power device is doped with the aluminum ion, and the semiconductor power device being doped with the aluminum ion comprises:
a substrate, represented by a first chemical formula, wherein the first chemical formula comprises an element semiconductor or a compound semiconductor;
a channel layer, located on the substrate, and represented by a second chemical formula, wherein the second chemical formula comprises another compound semiconductor;
a barrier layer, located on the channel layer, wherein the barrier layer comprises at least one compound, the compound located in at least one region of the barrier layer is represented by a third chemical formula, and the compound comprises an aluminum atom consisting of a ratio;
a source and a drain, wherein the source and the drain are compositions having a metal material, wherein the source and the drain are each independently located on the region; and
a gate, wherein the gate is a metal composition, and the gate is located between the source and the drain and outside the region.

20. The semiconductor power device according to claim 19, wherein the barrier layer comprises a first region and a second region outside the first region, the compound comprises a first compound located in the first region and a second compound located in the second region, the first compound comprises an aluminum atom consisting of a first ratio, the second compound comprises another aluminum atom consisting of a second ratio, and the first ratio and the second ratio are different.
